(19) United States
(12) Patent Application Publication
(10) Pub. No.: US 2006/0071330 A1
(43) Pub. Date: Apr. 6, 2006

(54) Semiconductor package

(75) Inventors: Shinji Suminoe, Tenri-shi (JP); Hiroyuki Nakanishi, Soraku-gun (JP); Yoko Komeda, Yamatokoriyama-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/240,802

(22) Filed: Oct. 3, 2005

(30) Foreign Application Priority Data
Oct. 4, 2004 (JP) 2004-291259

(51) Int. Cl. H01L 23/34

(52) U.S. Cl. 257/723

(57) ABSTRACT

A semiconductor package which is multifunctional, thin, and high in mounting reliability includes an insulating film; a first electronic component formed on one of the main surfaces of the insulating film; a second electronic component formed outwardly on the other of the main surfaces opposite to the one of the main surfaces; an external output terminal formed outwardly on the other of the main surfaces; and internal wiring formed in the insulating film so as to provide electrical continuity between the external output terminal and each of the first electronic component and the second electronic component. The insulating film is composed of a first insulating film and a second insulating film opposite to each other; the internal wiring is interposed between the first insulating film and the second insulating film, and the protruding end of the external output terminal is outside beyond the protruding end of the second electronic component.

### BACKGROUND OF THE INVENTION

1. Field of the Invention

The present invention relates to a semiconductor package.

2. Description of the Prior Art

In order to reduce electronic appliances such as mobile phones in size and weight, wafer-level chip scale packages (CSPs) have gotten attention as a semiconductor package to be mounted on an electronic appliance, because CSPs have the same size as semiconductor chips and can package a number of chips collectively while they are still in a wafer state.

A wafer-level CSP includes a semiconductor chip; an insulating layer which is formed on the semiconductor chip and is provided with internal wiring electrically continuous with the semiconductor chip; and external output terminals which are formed on the internal wiring and are electrically continuous with the internal wiring. On the other hand, in order to make semiconductor packages more multifunctional, there is a technique of mounting, in addition to a semiconductor chip, electronic components having different functions on a package by burying passive components such as a chip capacitor and a chip resistor in the insulating layer of a wafer-level CSP (See, e.g. Patent Document 1).

Patent Document 1: Japanese Patent Unexamined Publication No. 2002-299496 (FIG. 9)

The structure of the semiconductor package described in Patent Document 1 will be described as follows with reference to FIG. 3. A semiconductor package 300 includes an IC chip 301, an insulating layer 304 in contact with the IC chip 301, and solder bumps 305 as external output terminals in contact with the insulating layer 304. The insulating layer 304 contains internal electrodes 302 some of which are connected with the electrodes of the IC chip 301 and the others of which are connected with the solder bumps 305; vias 303 as metal posts for providing electrical continuity between the internal electrodes 302; and a passive component.

This passive component is connected with the electrodes of the IC chip 301 via the internal electrodes 302 and solder bumps 306. The passive component is composed of a silicon substrate 308; a capacitor 312 which is in contact with the silicon substrate 308 and is formed of an electrode 309, a dielectric film 310, and an electrode 311; a protective film 307 to cover the capacitor 312; and a conductive film 313 and a conductive plug 314 which provide electrical continuity between the solder bumps 306 and the electrodes 309, 311.

Thus, the technique described in Patent Document 1 makes a package multifunctional by burying passive components such as a chip capacitor and a chip resistor in the insulating layer of a wafer-level CSP. However, burying passive components inevitably makes the insulating layer thicker than the passive components, making it impossible to sufficiently reduce the thickness of the package. Moreover, burying passive components and metal posts (the vias 303) in the insulating layer makes these components and the insulating layer have a complicated shaped interface therebetween. As a result, when the package is mounted on a motherboard (substrate), the insulating layer is susceptible to exfoliation, which indicates low mounting reliability.

### SUMMARY OF THE INVENTION

The present invention has an object of providing a semiconductor package which is thin, multifunctional, and high in mounting reliability.

In order to achieve this object, the semiconductor package of the present invention includes: an insulating film; a first electronic component formed on one of the main surfaces of the insulating film; a second electronic component formed outwardly on the other of the main surfaces of the insulating film opposite in direction to the one of the main surfaces; an external output terminal formed outwardly on the other of the main surfaces in the same manner as the second electronic component; and internal wiring formed in the insulating film so as to provide electrical continuity between the external output terminal and each of the first electronic component and the second electronic component. The insulating film is composed of a first insulating film and a second insulating film opposite in direction to each other; the internal wiring is interposed between the first insulating film and the second insulating film; and the protruding end of the external output terminal is outside beyond the protruding end of the second electronic component.

In this structure, no electronic components are formed in the insulating films, and the first and second electronic components are formed on the opposed main surfaces of the insulating films. This allows the semiconductor package to be multifunctional in spite of the small thickness of the insulating films. Furthermore, making the protruding ends of the external output terminals outside beyond the protruding ends of the second electronic components can prevent the second electronic components from being damaged by bumping against the substrate during the surface mounting process, or the second electronic components from disturbing the connection between the external output terminals and the electrodes on the substrate side.

The internal wiring does not have the problem of disconnection or poor insulation because of being sandwiched between the first and second insulating films, thereby improving product yield and reliability for product quality. The interface between the insulating films and the components placed therein is simple shaped, as compared with that in the conventional package in which electronic components and metal posts are buried in the insulating film. This makes it harder for the insulating films to cause exfoliation, thereby improving the mounting reliability of the package. Note that the term “high in mounting reliability” indicates a low incidence of defective packaging during the surface mounting process.

In the conventional package, a plurality of metal posts (the vias 303) are essential to provide electrical continuity between the IC chip 301 and the external output terminals (solder bumps 305), thus making it impossible to sufficiently reduce the number of components of the package. In contrast, the aforementioned structure of the present invention does not need the metal posts, thereby reducing the number of components of the package.

In aforementioned structure of the present invention, the contact interface between the first and second insulating films, and the interface between the insulating films and the internal wiring function to reduce the propagation of stress strain due to the mounting of the second electronic components from the other of the main surfaces of the insulating films toward the one of the main surfaces thereof. Consequently, the first electronic component on the one of the main surfaces is prevented from being damaged by the stress strain caused on the other of the main surfaces.

In the semiconductor package of the present invention, the external output terminal may be composed of a core located in the center and a surface layer located outside the core; the core may have a higher melting point than the surface layer; and the end of the core may be outside beyond the protruding end of the second electronic component.

In order to improve the mounting reliability of the semiconductor package, the external output terminals in the wafer-level CSP are usually made of solder bumps such as solder balls which can be used for reflow mounting. However, when the semiconductor package is reflow-mounted on a substrate, the solder bumps are melted and crushed under the weight of the package so as to be deformed to a thickness of about ⅔ the original size. Therefore, when such solder bumps of the conventional art are used, the second electronic components must be prevented from being crushed and damaged by the substrate, and it becomes necessary for the solder bumps to have extra thickness for the deformation. This prevents the package from being made thinner.

Moreover, the solder bumps of the conventional art, which are deformed and laterally extended during the surface mounting process, may come into contact with adjacent ones and cause a short circuit. To avoid this, the solder bumps must be arranged at a predetermined pitch. This makes it impossible to narrow the pitch of the external output terminals to achieve multi-pin structure with high density.

In contrast, in the structure of the present invention, the surface layers of the external output terminals have a lower melting point than the cores located in the center, and the ends of the cores are outside beyond the protruding ends of the second electronic components. This allows the package to be mounted on the substrate, while the surface layers are melted but the cores are not melted. In this case, the cores, which are not melted, prevent the contact between the second electronic components and the substrate. Consequently, the external output terminals have significantly smaller extra thickness for the deformation due to melting, thereby being reduced in size. The external output terminals can also be arranged at a smaller pitch because they do not expand laterally. This allows the package to be further reduced in thickness and to have multi-pin structure.

In the semiconductor package of the present invention the core may be made of a material having a melting point higher than 260° C.; and the surface layer may be made of solder. The core of the external output terminal may be made of either metal or organic matter coated with metal.

This structure allows the melting point of the cores to be much higher than the reflow temperatures of general solders, and also allows the solders as the surface layers to connect the external output terminals with the substrate, so as to efficiently mount the package onto the substrate by the conventional solder reflow.

In the semiconductor package of the present invention the internal wiring may protrude between the core and the surface layer in such a manner as to be in contact with the inside of the surface layer; the internal wiring may have a higher melting point than the surface layer; and the e part of the internal wiring may be outside beyond the protruding end of the second electronic component.

This structure can prevent the contact between the second electronic components and the substrate before the package is mounted on the substrate, and can allow the package to be made much thinner and to have multi-pin structure with a larger number of pins.

In the semiconductor package of the present invention the first insulating film may be formed between the core of the external output terminal and the first electronic component.

In this structure, the first insulating film formed between the cores and the first electronic component prevents the cores, which are pressed during the surface mounting process, from bumping against the first electronic component.

The semiconductor package of the present invention may be a wafer-level chip scale package having an IC chip as the first electronic component.

This structure can reduce the package as small as the IC chip, thereby achieving a remarkable reduction of the semiconductor package in size and weight.

In the semiconductor package of the present invention, the first insulating film may have a thickness of not less than 3 μm.

In terms of thinning the package, the first and second insulating films are preferably as thin as possible. However, the first insulating film preferably has a thickness of not less than 3 μm in order to reduce the stress on it due to the mounting of the second electronic components and also to sufficiently reduce the electrical interference between the second electronic components and the first electronic component. Similarly, the second insulating film preferably has a thickness of not less than 3 μm in order to sufficiently reduce the electrical interference between the second electronic components and the internal wiring.

In the semiconductor package of the present invention, the internal wiring may have a multilayer structure having a barrier metal layer and a copper-containing conductive layer.

Copper (Cu) has the property of migrating in an insulating film; however, in the aforementioned structure the internal wiring has the barrier metal layer which reduces the dispersion of the copper contained in the conductive layer of the internal wiring or in the internal electrodes of the first electronic component into the insulating films, thereby preventing deterioration of the insulating films due to copper dispersion or a reduction in adhesion between the internal wiring and the insulating films.

In the semiconductor package of the present invention, the first electronic component and the second electronic component may have a metal layer therebetween, the metal layer being electrically connected with a ground.

This structure can further reduce the electrical interference between the first and second electronic components, or between each electronic component and the internal wiring.

According to the present invention thus described, no electronic components are formed in the insulating films, and the first and second electronic components are formed on the opposed main surfaces of the insulating films. This allows the semiconductor package to be multifunctional while the insulating films can be small in thickness. Furthermore, making the protruding ends of the external output terminals outside beyond the protruding ends of the second electronic components can prevent the second electronic components from being damaged by bumping against the substrate during the surface mounting process, or the second electronic components from disturbing the connection between the external output terminals and the electrodes on the substrate side.

The internal wiring does not have the problem of disconnection or poor insulation because of being sandwiched between the first and second insulating films, thereby improving product yield and reliability for product quality. The interface between the insulating films and the components placed therein is simple shaped, as compared with that in the conventional package in which electronic components and metal posts are buried in the insulating film. This makes it harder for the insulating films to cause exfoliation, thereby improving the mounting reliability of the package.

### BRIEF DESCRIPTION OF THE DRAWINGS

FIG. 1 is a schematic cross sectional view of an example of a semiconductor package according to the present invention.

FIG. 2 is a schematic cross sectional view of another example of the semiconductor package according to the present invention.

FIG. 3 is a schematic cross sectional view of a conventional semiconductor package.

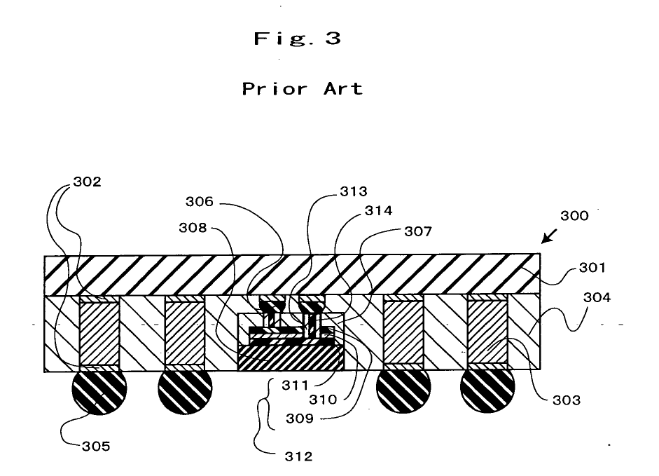

FIG. 4A and 4B are schematic cross sectional views of modified examples of the internal structure of an external output terminal of the semiconductor package shown in FIG. 2.

### REFERENCE MARKS IN THE DRAWINGS

100, 200 semiconductor package of the present invention
101, 201 first electronic component
102, 202 internal electrode
103, 203 first insulating film
104, 204 internal wiring
105, 205 second insulating film
106, 206 solder
107, 207 second electronic component
108, 208 external output terminal
108a, 208a core
108b, 208b solder
300 conventional semiconductor package
301 IC chip
302 internal electrode
303 via
304 insulating layer
305 solder bump
306 solder bump
307 protective film
308 silicon substrate
309 electrode
310 dielectric film
311 electrode
312 capacitor

### DESCRIPTION OF PREFERRED EMBODIMENTS

The best modes of the semiconductor package of the present invention will be described as follows.

### Embodiment 1

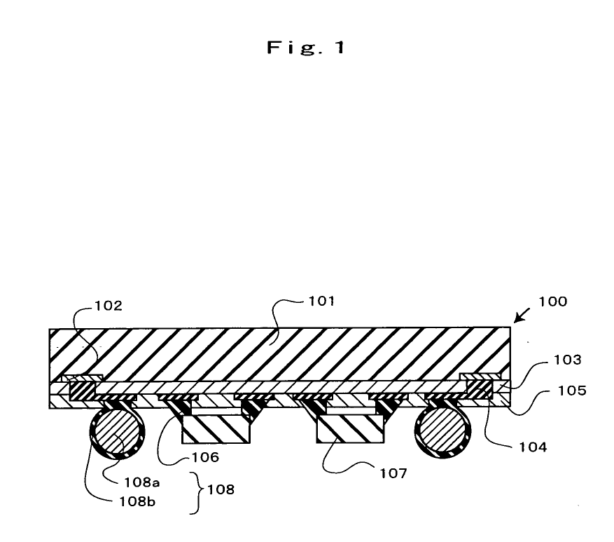

As shown in the schematic cross sectional view of FIG. 1, a semiconductor package 100 of the present embodiment includes an IC chip as a first electronic component 101; a first insulating film 103 which is in contact with one of the main surfaces of the IC chip; sheet-like internal wiring 104 which has a predetermined wiring pattern and is in contact with the first insulating film 103; a second insulating film 105 which is in contact with the internal wiring 104 and the first insulating film 103 and which faces the first insulating film 103 in such a manner as to sandwich the internal wiring 104; second electronic components 107 which are arranged outside the second insulating film 105; and spherical external output terminals 108 arranged outside the second insulating film 105 in the same manner as the second electronic components 107.

The IC chip and the external output terminals 108 are electrically continuous with each other by the connection between the external output terminals 108 and the internal electrodes 102 formed on the one of the main surfaces of the IC chip via the internal wiring 104.

The second electronic components 107 are connected with the internal wiring 104 via solders 106. The external output terminals 108 are each composed of a core 108a located in the center and a solder 108b located as a surface layer outside the core 108a, and are each connected to the internal wiring 104 via the solder 108b. The core 108a has a higher melting point than the surface layer, and the end of the core 108a is outside beyond the protruding end of each of the second electronic components 107.

The semiconductor package 100 of the present embodiment is manufactured as follows.

First of all, as the first electronic component 101, an IC chip having a thickness of about 625 μm and a main surface size of about 4.2 mm×4.2 mm is prepared. It goes without -saying-that the thickness and main surface size of the first electronic component 101 can be arbitrarily set in accordance with the design of the semiconductor package. As the first electronic component 101, the IC chip can be replaced by a passive component; however, in terms of reducing the semiconductor package in size and weight as a wafer-level CSP, it is preferable to select an IC chip as the first electronic component 101.

The internal electrodes 102 formed on one of the main surfaces of the first electronic component 101 are generally made of aluminum (Al), copper (Cu), a copper-aluminum alloy (AlCu), aluminum silicide (AlSi) or the like.

As a next step, the first insulating film 103 of about 3 to 50 μm thick is formed in contact with the one of the main surfaces of the IC chip by using polyimide, polybenzooxazole (PBO), benzocyclobutene (BCB) or the like as its material. Then, some parts of the first insulating film 103 that are on the internal electrodes 102 are removed to partly expose the internal electrodes 102 so that internal wiring 104, which will be described later, can be connected with the internal electrodes 102.

As a next step, the sheet-like internal wiring 104 having a predetermined wiring pattern is formed in contact with the first insulating film 103 and the exposed parts of the internal electrodes 102. The internal wiring 104 is composed of an about 0.05 to 0.30 μm-thick barrier metal layer of titanium (Ti), chrome (Cr) or the like, and an about 3 to 50 μm-thick conductive layer made of copper. The term “predetermined wiring pattern” means an internal wiring pattern for providing electrical continuity between the internal electrodes 102 of the first electronic component 101 and both the external output terminals 108 and the second electronic components 107, which will be described later. In terms of reducing wiring resistance, the conductive layer preferably contains a copper layer. The conductive layer does not need to consist of the copper layer alone, but may have a multilayer structure further including, e.g. a nickel layer and a gold layer.

Although copper (Cu) has the property of migrating in an insulating film, the barrier metal layer formed in the internal wiring 104 reduces the dispersion of the copper contained in the internal electrodes 102 and in the conductive layer of the internal wiring 104 into the insulating films 103 and 105, thereby preventing deterioration of the insulating films 103 and 105 due to copper dispersion or a reduction in adhesion between the internal wiring 104 and the insulating films 103,105.

As a next step, the second insulating film 105 of about 3 to 50 μm thick is formed in contact with the first insulating film 103 and the internal wiring 104 by using polyimide, polybenzooxazole (PBO), benzocyclobutene (BCB) or the like as its material. Then, some parts of the second insulating film 105 that are on the internal wiring 104 are removed to expose predetermined parts of the internal wiring 104 so that the second electronic components 107 and the external output terminals 108, which will be described later, can be connected with the internal wiring 104.

As a final step, the external output terminals 108 and the second electronic components 107 are connected with the exposed parts of the internal wiring 104 via solders 108b and solders 106, respectively, so as to complete the semiconductor package 100.

The external output terminals 108 each have a spherical core 108a (whose melting point is not less than 260° C.) in the center. The core 108a is formed of either metal like copper or organic matter like a divinylbenzene cross-linked copolymer, other polyimide, or high heat resistant rubber (whose melting point is not less than 260° C.), and of one or more metal layers coating its outer surface so that the core 108a has an outer diameter of about 400 μm. The core 108a is further coated with the solder 108b, which is about 20 μm thick and made of Sn/Pb or Sn/Ag/Cu.

The external output terminals 108 are arranged at a pitch of about 600 μm in such a manner that the respective ends of the cores 108a are about 400 μm outside the second insulating film 105. It goes without saying that the size and shape of the cores 108a and the length of the parts of the cores 108a that is beyond the second insulating film 105 are arbitrarily set in accordance with the design of the semiconductor package. The length of the parts of the cores 108a that is beyond the second insulating film 105 is preferably set as small as possible to reduce the package 100 in thickness. However, in terms of preventing the second electronic components 107 from bumping against the substrate during the surface mounting process, the ends of the cores 108a are required to be outside beyond the protruding ends of the second electronic components 107, and are preferably beyond them by not less than 100 μm.

The external output terminals 108 can be composed of solder bumps exclusively made of solder with no cores 108a in their center. However, it is more preferable for the external output terminals 108 to have the aforementioned structure in which the cores 108a are located in the center and the conductive surface layers are located outside the cores 108a, and the cores 108 have a relatively higher melting point than the surface layers. The reason for this preference is as follows.

In the case where solder bumps not having the cores in the center are used, when the semiconductor package is reflow-mounted on a substrate, the solder bumps are melted and crushed under the weight of the package so as to be deformed to a thickness of about ⅔ the original size. In order to prevent the crushing damage to the second electronic components during the surface mounting process, the solder bumps are required to have extra thickness for the deformation. On the other hand, the prevention of short circuit between adjacent solder bumps during the deformation makes it impossible to arrange the solder bumps at a small pitch. Thus, in order to achieve a package which is thin and has multi-pin structure, it is preferable to use the external output terminals 108 having the aforementioned structure with the cores 108a in their center.

The materials for the cores 108a and the surface layers can be selected so that the cores 108a can have a relatively higher melting point than the surface layers. It is preferable that the cores 108a be made of a material having a melting point not less than 260° C. and that the surface layers be made of solder, because this allows the use of reflow method for the surface mounting of the package 100.

The second electronic components 107 are formed of chip capacitors having a thickness of about 0.3 mm and a main surface size of about 0.6 mm×0.3 mm, and are located as close to the external output terminals 108 as 300 μm at the closest point. It goes without saying that the size of the second electronic components can be arbitrarily set in accordance with the design of the semiconductor package. It also goes without saying that the second electronic components 107 can be formed of other passive components such as chip resistors, or IC chips instead of the chip capacitors. When the second electronic components 107 are formed of IC chips, the IC chips are preferably grained so as to be thinner than the height of the external output terminals.

In terms of thinning the package 100, the first and second insulating films 103 and 105 are preferably as thin as possible. However, the second insulating film 105 preferably has a thickness of not less than 3 μm in order to reduce the stress on its surface due to the mounting of the second electronic components 107, and also to reduce the electrical interference between the second electronic components 107 and the internal wiring 104. Similarly, the first insulating film 103 preferably has a thickness of not less than 3 μm in order to sufficiently reduce the electrical interference between the first electronic component 101 and the internal wiring 104.

In the semiconductor package 100 of the present embodiment, no electronic components are formed in the insulating films 103 and 105, and the first and second electronic components 101 and 107 are formed on the opposed main surfaces of the insulating films 103 and 105. This allows the semiconductor package 100 to be multifunctional. while the insulating films 103 and 105 can be small in thickness. Furthermore, making the protruding ends of the external output terminals 108 outside beyond the protruding ends of the second electronic components 107 can prevent the second electronic components 107 from being damaged by bumping against the substrate during the surface mounting process, or the second electronic components 107 from disturbing the connection between the external output terminals 108 and the electrodes on the substrate side.

The internal wiring 104 does not have the problem of disconnection or poor insulation because of being sandwiched between the first and second insulating films 103 and 104, thereby improving product yield and reliability for product quality. The interface between the insulating films 103, 105 and the components placed therein is simple shaped, as compared with that in the conventional package in which electronic components and metal posts are buried in the insulating film. This makes it harder for the insulating films 103 and 105 to cause exfoliation, thereby improving the mounting reliability of the package 100. As another advantage of the present embodiment, not requiring metal posts used in the conventional package allows the package 100 to have a reduced number of components.

The contact interface between the first and second insulating films 103 and 105, and the interface between the insulating films 103, 105 and the internal wiring 104 function to reduce the propagation of stress strain due to the mounting of the second electronic components 107 from the other of the main surfaces of the insulating films 103 and 105 toward the one of the main surfaces thereof. Consequently, the first electronic component 101 on the one of the main surfaces is prevented from being damaged by the stress strain caused on the other of the main surfaces.

The surface layers of the external output terminals 108 have a lower melting point than the cores 108a located in the center, and the ends of the cores 108a are outside beyond the protruding ends of the second electronic components 107. This allows the package 100 to be mounted on the substrate, while the surface layers are melted but the cores 108a are not melted. In this case, the cores 108a, which are not melted, prevent the contact between the second electronic components 107 and the substrate. Consequently, the external output terminals 108 have significantly smaller extra thickness for the deformation due to melting, thereby being reduced in size. The external output terminals 108 can also be arranged at a smaller pitch because they do not expand laterally. This allows the package 100 to be further reduced in thickness and to have multi-pin structure.

### Embodiment 2

Embodiment 2 of the present invention will be described as follows with reference to accompanying drawings. Substantially the same components as those in embodiment 1 will not be described again.

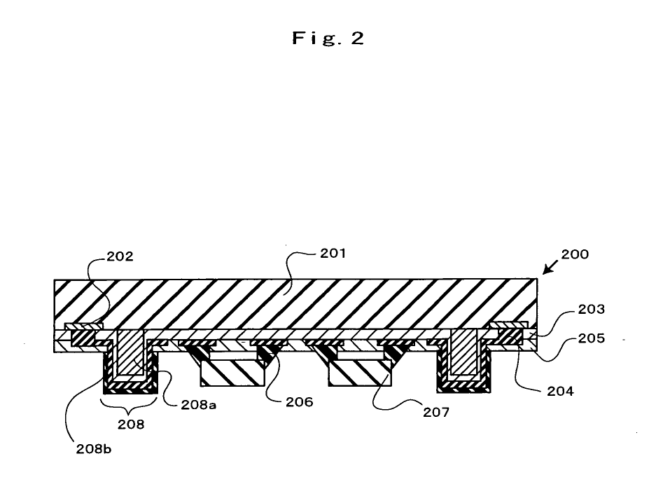

As shown in the schematic cross sectional view of FIG. 2, a semiconductor package 200 of the present embodiment includes an IC chip as a first electronic component 201; cylindrical cores 208a which are formed outwardly on one of the main surfaces of the IC chip; a first insulating film 203 which is in contact with the one of the main surfaces of the IC chip and the cores 208a; sheet-like internal wiring 204 which is in contact with the first insulating film 203 and has a predetermined wiring pattern; a second insulating film 205, which will be described below; second electronic components 207 which are outside beyond the second insulating film 205; and solder 208b as surface layers to cover the extended parts of the internal wiring 204 that are outside beyond the second insulating film 205. The second insulating film 205 is in contact with the internal wiring 204 and the first insulating film 203 except for their parts protruding to cover the cores 208a, and is opposed to the first insulating film 203 in such a manner as to sandwich the non-extended parts of the internal wiring 204.

In the description hereafter, external output terminals 208 refer to the parts which are outside beyond the second insulating film 205 and which consist of the extended parts of the first insulating film 203, the extended parts of the internal wiring 204, and the solders 208b coating these extended parts. The external output terminals 208 and the IC chip are electrically continuous with each other by the connection between the internal electrodes 202 formed on the one of the main surfaces of the IC chip and the solders 208b via the internal wiring 204. The second electronic components 207 are connected to the internal wiring 204 via the solders 206.

The cores 208a have a higher melting point than the surface layers, and the ends of the cores 208a are outside beyond the protruding ends of the second electronic components 207.

The semiconductor package 200 of the present embodiment is manufactured as follows.

The cylindrical cores 208a are formed at a pitch of about 500 μm by photo processing or printing in such a manner as to be in contact with the one of the main surfaces of the IC chip. The cores 208a are made of an organic insulator such as polyimide or high heat resistant rubber, and have a melting point of 260° C. and a main surface of about 200 μm in thickness and about 300 μm in diameter.

As a next step, the first insulating film 203 is formed in contact with the one of the main surfaces of the IC chip and the cores 208a. Then, some parts of the first insulating film 203 that are on the internal electrodes 202 are removed to partly expose the internal electrodes 202 so that internal wiring 204, which will be described later, can be connected with the internal electrodes 202 of the IC chip. The first insulating film 203 is identical in material and thickness to the first insulating film 103 of embodiment 1, and the other components described hereinafter are also identical to the counterparts in embodiment 1 unless otherwise mentioned.

As a next step, the sheet-like internal wiring 204 having the predetermined wiring pattern and provided with the barrier metal layer and the conductive layer is formed in contact with the first insulating film 203 and the exposed parts of the internal electrodes 202.

As a next step, the second insulating film 205 is formed in such a manner as to be in contact with the internal wiring 204 and the first insulating film 203 except for their parts protruding to cover the cores 208a, and also in such a manner as to be opposed to the non-extended parts of the first insulating film 203 so as to sandwich the non-extended parts of the internal wiring 204. Then, some regions of the second insulating film 205 that are on the internal wiring 204 are removed to partly expose the internal wiring 204 so that the second electronic components 207 and the external output terminals 208, which will be described later, can be connected with the internal wiring 204.

As a final step, the extended parts of the internal wiring 204 are coated with the solders 208b so as to form the external output terminals 208. The second electronic components 207 are connected on the exposed parts of the internal wiring 204 via the solders 206, thereby completing the semiconductor package 200.

The solders 208b are about 100 μm thick, and the extended parts of the internal wiring 204 are about 300 μm beyond the second insulating film 205. However, it goes without saying that the length of the extended parts of the internal wiring 204 can be arbitrarily set in accordance with the design of the semiconductor package. For example, the length may be controlled by changing the size of the cores 208a. In terms of reducing the package in thickness, the length is preferably as small as possible. However, for the purpose of preventing the electronic components from bumping against the substrate during the surface mounting process, the extended parts of the internal wiring 204 are required to be outside beyond the protruding ends of the second electronic components 207, and are preferably at least about 100 μm beyond the protruding ends.

The second electronic components 207 are formed of chip capacitors having a thickness of about 0.2 mm and a main surface size of about 0.4 mm×0.2 mm, and are located as close to the external output terminals 208 as about 500 μm at the closest point. It goes without saying that the size of the second electronic components can be arbitrarily set in accordance with the design of the semiconductor package. It also goes without saying that the second electronic components 207 can be formed of other passive components such as chip resistors, or IC chips instead of the chip capacitors. When the second electronic components 207 are formed of IC chips, the IC chips are preferably grained so as to be thinner than the height of the external output terminals as mentioned above.

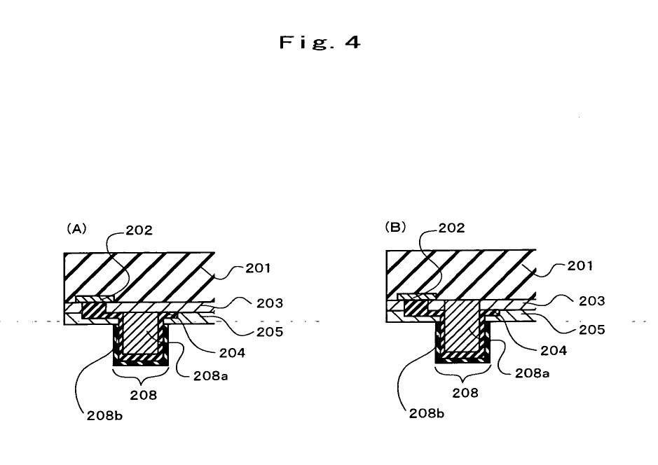

The location of the cores 208a inside the external output terminals 208 may be between the first electronic component 201 and the extended parts of the internal wiring 204. Besides the aforementioned location of the cores 208a shown in FIG. 2, FIG. 4A shows another structure in which the first insulating film 203 is in contact with and between the cores 208a and the first electronic component 201, and the extended parts of the internal wiring 204 are in contact with the extended parts of the cores 208a. FIG. 4B shows further another structure in which the cores 208a are in contact with the first electronic component 201, and the protruding parts of the cores 208a are in contact with the extended parts of the internal wiring 204. The structure shown in FIG. 4A is particularly preferable because the first insulating film 203 formed between the cores 208a and the first electronic component 201 prevents the cores 208a, which are pressed during the surface mounting process, from bumping against and damaging the first electronic component 201.

In the present embodiment, the first and second electronic components 201 and 207 are arranged on the opposed main surfaces of the thin insulating films 203 and 205, and the external output terminals 208 are formed outside beyond the second electronic components 207, so that the semiconductor package 200 can be multifunctional and thin. In addition, the prevention of the pressure damage on the second electronic components 207 or exfoliation of the insulating films 203 and 205 during the surface mounting process allows the package 200 to be higher in mounting reliability.

The surface layers of the external output terminals 208 have a lower melting point than the cores 208a located in the center and the internal wiring, so that the package 200 can be mounted on the substrate while the surface layers are melted but the extended parts of the internal wiring 204 and the cores 208a are not melted. This difference in melting point allows the extended parts of the internal wiring 204 outside beyond the protruding ends of the second electronic components 207 to prevent the second electronic components 207 from bumping against the substrate during the surface mounting process. The difference in melting point also allows the external output terminals 208 to have a smaller amount of deformation during the surface mounting process, that is, a significantly smaller extra thickness for the deformation. The external output terminals 208 thus reduced in size can further reduce the package 200 in size, and can also be arranged at a smaller pitch, thereby providing the package 200 with multi-pin structure.

Furthermore, the internal wiring 204 does not have the problem of disconnection or poor insulation because of being sandwiched between the first and second insulating films 203 and 205, thereby improving product yield and reliability for product quality. In addition, the interface between the insulating films 203, 205 and the components placed therein is simple shaped, as compared with that in the conventional package in which electronic components and metal posts are buried in the insulating film. This makes it-harder for the insulating films 203 and 205 to cause exfoliation, thereby improving the mounting reliability of the package 200. As an additional advantage of the present embodiment, not requiring metal posts used in the conventional package allows the package 200 to have a reduced number of components.

The contact interface between the first and second insulating films 203 and 205, and the interface between the insulating films 203, 205 and the internal wiring 204 function to reduce the propagation of stress strain due to the mounting of the second electronic components 207 from the other of the main surfaces of the insulating films 203 and 205 toward the one of the main surfaces thereof. Consequently, the first electronic component 201 on the one of the main surfaces is prevented from being damaged by the stress strain caused on the other of the main surfaces.

### Additional Description

(1) In embodiments 1 and 2, the second insulating film and the solders are formed directly on the internal wiring. Alternatively, after being formed onto the first insulating film, the internal wiring may be coated with a nickel (Ni) layer of about 3 to 10 μm thick either on its whole surface or on its parts to be exposed after the formation of the second insulating film. This coating is preferable because it prevents the dispersion of the solders and the copper contained in the conductive layer.

After being coated with the nickel layer, the parts of the internal wiring that are to be exposed to form the second insulating film may be further coated with a gold (Au) layer of about 0.01 to 0.3 μm thick. This additional coating is preferable because it prevents the oxidation of the nickel layer before the formation of the solders, and also improves the wettability of the solders.

(2) In embodiments 1 and 2, the electrical interference between the internal wiring and each of the first electronic component and the second electronic components and also between the first and second electronic components is reduced by controlling the thickness of the insulating films. When the electrical interference is high, it is preferable to interpose a metal layer electrically connected with the ground between the first electronic component and the second electronic components because it further reduces the interference. In order to improve the adhesion between the metal layer and the insulating films, the metal layer is preferably in the form of a mesh.

As described hereinbefore, the present embodiment allows a semiconductor package to be more multifunctional, thinner, and higher in mounting reliability by arranging the first and second electronic components on the opposed main surfaces of the thin insulating films and by forming the external output terminals outside beyond the second electronic components. Thus, the semiconductor package has wide industrial applicability.

What is claimed is:

1. A semiconductor package comprising:
an insulating film;
a first electronic component formed on one of main surfaces of said insulating film;
a second electronic component formed outwardly on an other of the main surfaces of said insulating film opposite in direction to said one of the main surfaces;
an external output terminal formed outwardly on said other of the main surfaces in a same manner as the second electronic component; and
internal wiring formed in said insulating film so as to provide electrical continuity between said external output terminal and each of the first electronic component and the second electronic component, wherein
said insulating film is composed of a first insulating film and a second insulating film opposite in direction to each other;
said internal wiring is interposed between the first insulating film and the second insulating film; and
a protruding end of said external output terminal is outside beyond a protruding end of the second electronic component.

2. The semiconductor package of claim 1, wherein
said external output terminal is composed of a core located in a center and a surface layer located outside said core;
said core has a higher melting point than said surface layer; and
an end of said core is outside beyond the protruding end of the second electronic component.

3. The semiconductor package of claim 2, wherein
said internal wiring protrudes between said core and said surface layer in such a manner as to be in contact with an inside of said surface layer;
said internal wiring has a higher melting point than said surface layer; and
an extended part of said internal wiring is outside beyond the protruding end of the second electronic component.

4. The semiconductor package of claim 2, wherein
said core is made of a material having a melting point higher than 260° C.; and
said surface layer is made of solder.

5. The semiconductor package of claim 3, wherein
the first insulating film is formed between said core of said external output terminal and the first electronic component.

6. The semiconductor package of claim 4, wherein
said core of said external output terminal is made of one of metal and organic matter coated with metal.

7. The semiconductor package of claim 1, which is a wafer-level chip scale package having an IC chip as the first electronic component.

8. The semiconductor package of claim 1, wherein
the first insulating film has a thickness of not less than 3 μm.

9. The semiconductor package of claim 1, wherein
said internal wiring has a multilayer structure having a barrier metal layer and a copper-containing conductive layer.

10. The semiconductor package of claim 1, wherein
the first electronic component and the second electronic component have a metal layer therebetween, the metal layer being electrically connected with a ground.
